(19) United States
(12) Patent Application Publication
(10) Pub. No.: US 2025/0336753 A1
(43) Pub. Date: Oct. 30, 2025

(54) AIR CAVITY PACKAGE AND METHODS FOR FORMING SAME

(71) Applicant: Qorvo US, Inc., Greensboro, NC (US)

(72) Inventors: Peter Haase, Richardson, TX (US); MD Hasnine, Richardson, TX (US)

(21) Appl. No.: 19/083,638

(22) Filed: Mar. 19, 2025

Related U.S. Application Data
(60) Provisional application No. 63/640,510, filed on Apr. 30, 2024.

(51) Int. Cl. H01L 23/367; H01L 21/50; H01L 23/00; H01L 23/10; H01L 23/498

(52) U.S. Cl. CPC H01L 23/3675; H01L 21/50; H01L 23/10; H01L 23/49816; H01L 23/49838; H01L 24/48; H01L 2224/48227

(57) ABSTRACT

An air cavity package and methods for making same are disclosed. In one aspect, a cavity is delimited by a metalized laminate structure and side walls with interior conductive elements. The metalized laminate structure has signal routing conductors that couple to the interior conductive elements of the side walls. The metalized laminate structure also has a heat sink structure. A die or component is placed on the heat sink structure and the cavity is closed by a lid. The interior conductive elements are exposed so that they may be configured to couple to a board or the like for integration into an electronic device.

### PRIORITY APPLICATION

The present application claims priority to U.S. Provisional Patent Application Ser. No. 63/640,510, entitled AIR CAVITY PACKAGE AND METHODS FOR FORMING SAME, filed on Apr. 30, 2024, the contents of which is hereby incorporated by reference in its entirety.

### BACKGROUND

### I. Field of the Disclosure

The technology of the disclosure relates generally to package design for high-power circuits and particularly to techniques to cool such packages.

### II. Background

Electronic devices abound in modern society. The prevalence of these computing devices is driven in part by the many functions that are now enabled on such devices. One popular and increasingly complicated type of electronic device is the communication transceiver. Numerous standards for wireless and wire-based communication exist, frequently requiring different circuitry to send and receive signals compliant with these standards. One common feature for transceivers is the presence of a power amplifier in the transmit chain. Such power amplifiers may generate substantial heat during normal operation. If the heat remains proximate the power amplifier, operation of the power amplifier may be negatively impacted. While power amplifiers are a frequent culprit in the generation of heat, other circuits may also generate unwanted heat. Removing this heat from the proximity of such heat-generating circuits provides room for innovation.

### SUMMARY

Aspects disclosed in the detailed description include an air cavity package and methods for forming same. In particular, a cavity is delimited by a metalized laminate structure and side walls with interior conductive elements. The metalized laminate structure has signal routing conductors that couple to the interior conductive elements of the side walls. The metalized laminate structure also has a heat sink structure. A die or component is placed on the heat sink structure and the cavity is closed by a lid. The interior conductive elements are exposed so that they may be configured to couple to a board or the like for integration into an electronic device.

In this regard, in one aspect, a package is disclosed. The package includes a metalized laminate comprising a heat spreader element and a sidewall positioned on a first side of the metalized laminate, the sidewall comprising an external contact configured to couple electrically to an external substrate. The package also includes a die positioned on the first side of the metalized laminate proximate the heat spreader element and a lid connected to the sidewall, proximate the external contact and spaced from the metalized laminate, wherein the lid, the metalized laminate and the sidewall delimit an air cavity with the die positioned inside the air cavity.

In another aspect, a communication device is disclosed. The communication device includes a transceiver comprising a high-power power amplifier, the high-power power amplifier positioned in a die in an air cavity, the air cavity delimited by a package. The package includes a metalized laminate comprising a heat spreader element and a sidewall positioned on a first side of the metalized laminate, the sidewall comprising an external contact configured to couple electrically to an external substrate. The package also includes the die positioned on the first side of the metalized laminate proximate the heat spreader element and a lid connected to the sidewall, proximate the external contact and spaced from the metalized laminate, wherein the lid, the metalized laminate and the sidewall delimit the air cavity with the die positioned inside the air cavity.

In another aspect, a method of forming a top-side cooled air cavity is disclosed. The method includes forming a metalized laminate structure comprising a heat spreader element, positioning a sidewall on a first side of the metalized laminate structure, and positioning a die on the first side of the metalized laminate structure. The method also includes positioning a lid over the die on the sidewall, thereby delimiting an air cavity with the die inside the air cavity and exposing an external contact on a surface of the sidewall distal from the first side of the metalized laminate structure.

### BRIEF DESCRIPTION OF THE DRAWINGS

FIG. 1 is a side elevation view of an air cavity module mounted on a first laminate wherein a die in the air cavity module is mounted on a second laminate where heat flows into the laminates;

FIG. 2 is a side elevation view of a top-cooled air cavity that removes heat from the laminate according to aspects of the present disclosure;

FIG. 3 is a flowchart showing a process of making a top-cooled air cavity according to a first aspect of the present disclosure;

FIGS. 4A-4K are cross-sectional side views of the steps of the process of FIG. 3;

FIG. 5 is a cross-sectional side view of a finished product made according to the process of FIG. 3;

FIG. 6 is a flowchart showing a process of making a top-cooled air cavity according to a second aspect of the present disclosure;

FIGS. 7A-7H are cross-sectional side views of the steps of the process of FIG. 6;

FIG. 8 is a cross-sectional side view of a finished product made according to the process of FIG. 6; and

FIG. 9 is a block diagram of an electronic device, which may include a package of FIG. 5 or 8 formed according to the processes of FIG. 3 or 6 according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Additionally, to the extent that the term “approximately” is used in the claims, it is herein defined to be within five percent (5%).

Aspects disclosed in the detailed description include an air cavity package and methods for forming same. In particular, a cavity is delimited by a metalized laminate structure and side walls with interior conductive elements. The metalized laminate structure has signal routing conductors that couple to the interior conductive elements of the side walls. The metalized laminate structure also has a heat sink structure. A die or component is placed on the heat sink structure and the cavity is closed by a lid. The interior conductive elements are exposed so that they may be configured to couple to a board or the like for integration into an electronic device.

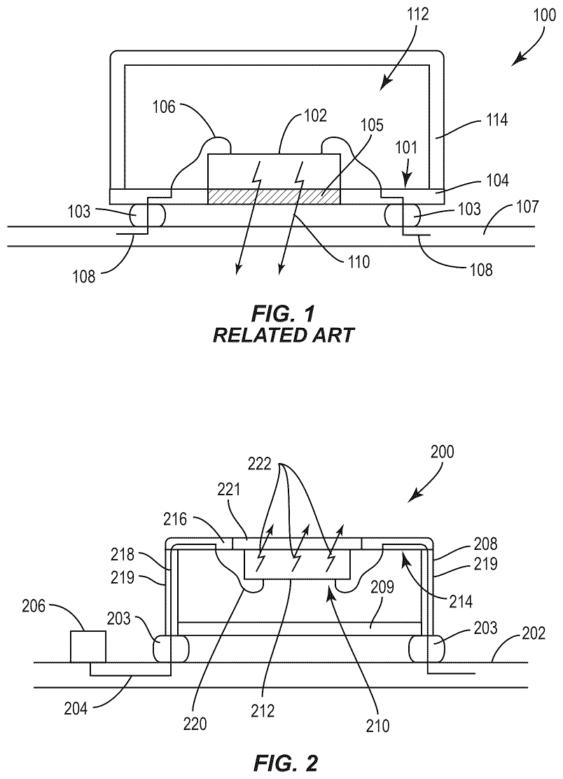

Before addressing aspects of the present disclosure, a brief overview of how heat may be trapped near a heat-producing die is provided with reference to FIG. 1. A discussion of aspects of the present disclosure that provide an improved technique to remove heat from die proximity begins below with reference to FIG. 2.

In this regard, FIG. 1 illustrates an air cavity module or air cavity system 100 where a die 102 is placed on a surface 101 of a metalized laminate structure 104. Wire bonds 106 may couple the internal circuitry of the die 102 to conductors 108 in the metalized laminate structure 104. Typically, the metalized laminate structure 104 is then mounted on another laminate 107, such as a printed circuit board (PCB) made from FR4 or similar material, through a conductive material such as solder balls or simply solder 103. It is possible that the metalized laminate structure 104 is also made with FR4, although more commonly, there may be a heat slug 105 in the metalized laminate structure 104. In contrast to the metal heat slug 105, FR4, in particular, is a poor thermal conductor. Accordingly, heat 110 generated in the die 102 may travel into the metalized laminate structure 104 and the laminate 107 and remain relatively confined proximate the die 102. This heat buildup may result in changes in the operation of the circuits within the die 102 and, in extreme cases, may damage the circuits such that they are inoperable. This trapped heat is exacerbated when the die 102 is encapsulated within an air cavity 112 delimited by an over-structure 114 formed, typically from mold compound. The use of air cavities such as air cavity 112 is desirable for certain radio frequency (RF) applications where the dielectric property of air compared to mold compound may give performance advantages.

Aspects of the present disclosure contemplate repositioning the heat-generating die and any corresponding heat slug to an exposed portion of the structure that delimits the air cavity such that an exposed heat sink (e.g., a metal heat slug) may more readily remove heat from the area proximate the heat-generating die. In a particular aspect, the air cavity module is flipped so that the die is now on the underside of a top surface of the structure, and conductors are positioned within the walls of the structure to provide electrical connections from the circuits inside the die to the mounting structure. The exposed heat sink of the air cavity module can now be thermally coupled to other heat dissipating elements.

In this regard, FIG. 2 illustrates a package 200 that is configured to be positioned on a mounting structure 202 such as through solder balls or solder 203. The mounting structure 202 may be a PCB and include surface-mounted conductors or internal conductors 204 that provide electrical connections from the package 200 other elements 206 (e.g., another die, surface-mounted devices (SMD) such as inductors or the like) within a computing device (not shown explicitly).

With continued reference to FIG. 2, the package 200 includes a structure 208 including a lid 209 that delimits an air cavity 210. A heat-generating die 212 is mounted on an interior surface 214 of a top metalized laminate 216 within the air cavity 210. The structure 208 includes interior conductors 218 within laminate mold walls 219. The conductors 218 provide electrical connections from the heat-generating die 212 to the conductors 204. Wire bonds 220 may couple the die to the interior conductors 218. A heat slug 221 positioned in the metalized laminate 216 may act as a first heat sink and may help remove heat from the area proximate the heat-generating die 212.

The positioning of the heat-generating die 212 on the top metalized laminate 216 allows heat 222 to escape away from the mounting structure 202. Further, a heat sink or other heat-dissipating elements (not shown) may be positioned on the metalized laminate 216, as better explained below.

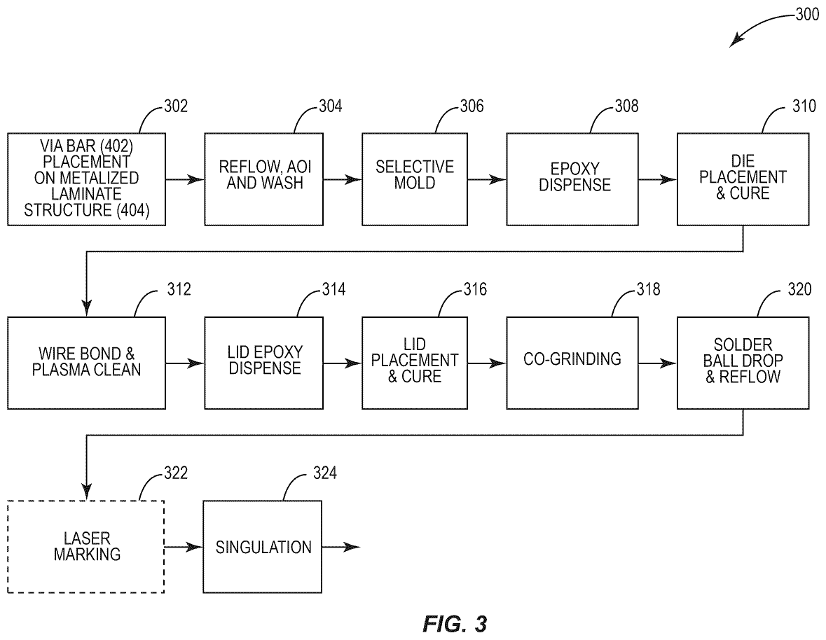

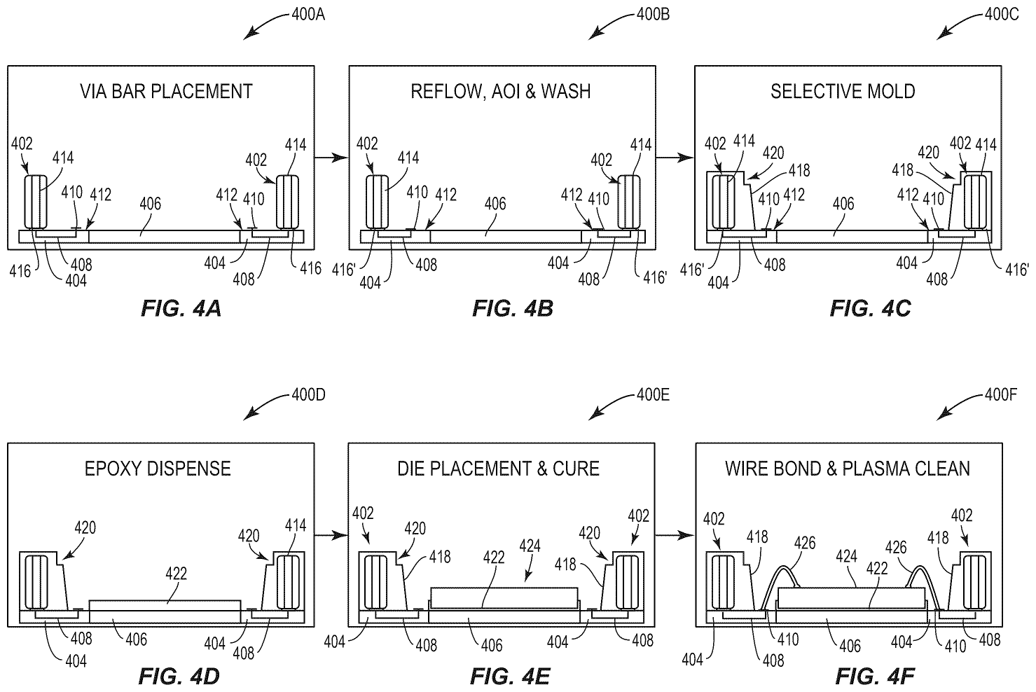

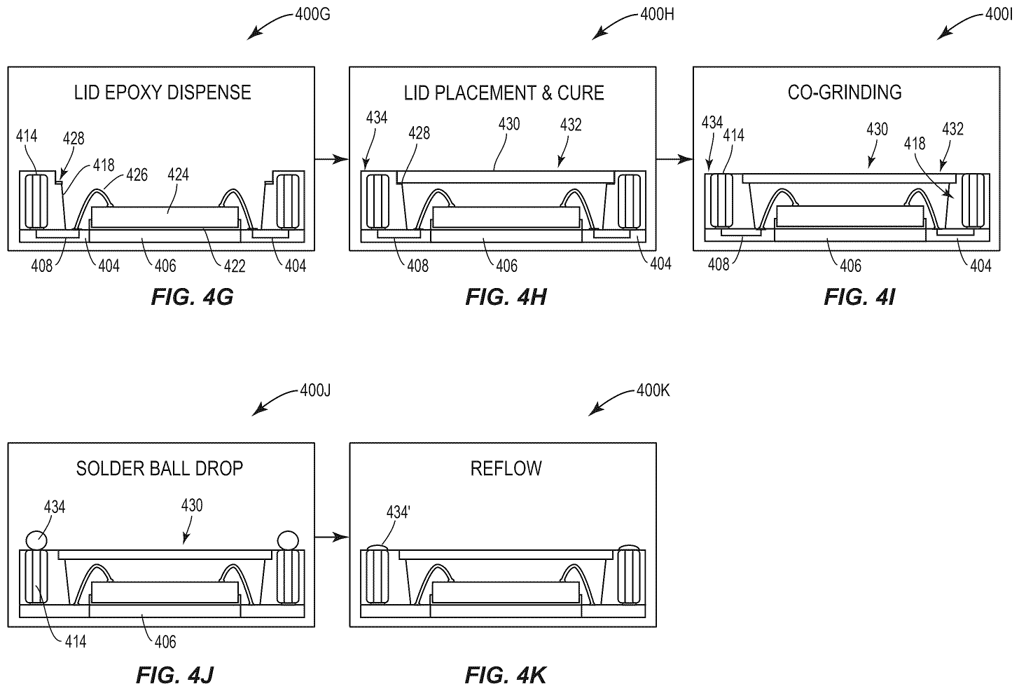

FIG. 3 outlines a process 300 for forming an air cavity package with improved heat removal according to a first aspect of the present disclosure. FIGS. 4A-4K provide cross-sectional views of the intermediate structures 400A-400K as the process 300 is performed.

In this regard, the process 300 begins with via bar 402 placement on a metalized laminate structure 404 (block 302, FIG. 4A) to create initial intermediate structure 400A. In an exemplary aspect, the metalized laminate structure 404 contains a heat slug or heat spreader element 406, which may be, for example, a copper plate. The metalized laminate structure 404 also includes internal conductors 408, which couple to pads 410 on a surface 412 of the metalized laminate structure 404. The internal conductors 408 provide an electrical connection from the pads 410 to vias 414 in the via bar 402. The via bar 402 may be a preformed structure like a ring frame or e-bar that has discrete electrically conductive vias 414 therein. This placement may be done using standard techniques such as solder paste 416 or flux printing.

The process 300 continues by using a reflow, automated optical inspection (AOI), and wash (block 304, FIG. 4B) to clean any paste or flux residue and create intermediate structure 400B. The intermediate structure 400B is substantially similar, but the paste 416 has been cleaned to a desired shape of paste 416′.

The process 300 continues by applying a selective mold 418 (block 306, FIG. 4C) to cover the via bar 402 while leaving the active area of the surface 412 exposed. That is, pads 410 are not covered. Note further the mold 418 is shaped to provide an edge (also referred to as a shoulder or lip) 420.

The process 300 continues with a die epoxy layer 422 being dispensed (block 308, FIG. 4D) on the heat spreader element 406 to create intermediate structure 400D. As illustrated, the die epoxy layer 422 is co-extensive with the heat spreader element 406 but does not have to be. Likewise, it is possible that the die epoxy layer 422 spills past the edges of the heat spreader element 406. However, maximal heat transfer suggests that the heat spreader element 406 be at least as large as the die epoxy layer 422.

The process 300 continues by placing a die 424 on the die epoxy layer 422 and curing the die epoxy layer 422 (block 310, FIG. 4E). The die 424 may include internal circuitry (now shown explicitly), such as a high-power power amplifier or the like that generates heat during operation. Placement and curing may be through conventional pick-and-place technology and curing according to the nature of the epoxy (e.g., infrared curing, ultraviolet curing, heat curing, or the like).

The process 300 continues by wire bonding the die 424 to the pads 410 with wire bonds 426 followed by plasma cleaning (block 312, FIG. 4F) to form intermediate structure 400F. The wire bonding electrically connects the interior circuitry of the die 424 to the pads 410, the internal conductors 408, and the vias 414.

The process 300 continues by dispensing a lid epoxy 428 (block 314, FIG. 4G) on the edge 420 to form intermediate structure 400G. A lid 430 is then placed on the edge 420 and the lid epoxy 428 is cured (block 316, FIG. 4H) to form intermediate structure 400H. The lid 430 may be made from FR4 or liquid crystal polymer (LCP).

The process 300 continues by co-grinding (block 318, FIG. 4I) a surface 432 of the lid 430 and a solder ball 434 of the mold 418 to expose the via 414.

The process 300 continues by performing a solder ball 434 drop and reflow (block 320, FIGS. 4J and 4K) to form intermediate structures 400J, 400K. That is a solder ball 434 is initially placed on the via 414 and then the reflow creates electrical contact 434′. Optionally the package may be laser marked (e.g., with a trademark, part number, or the like) (block 322) and then singulated (block 324).

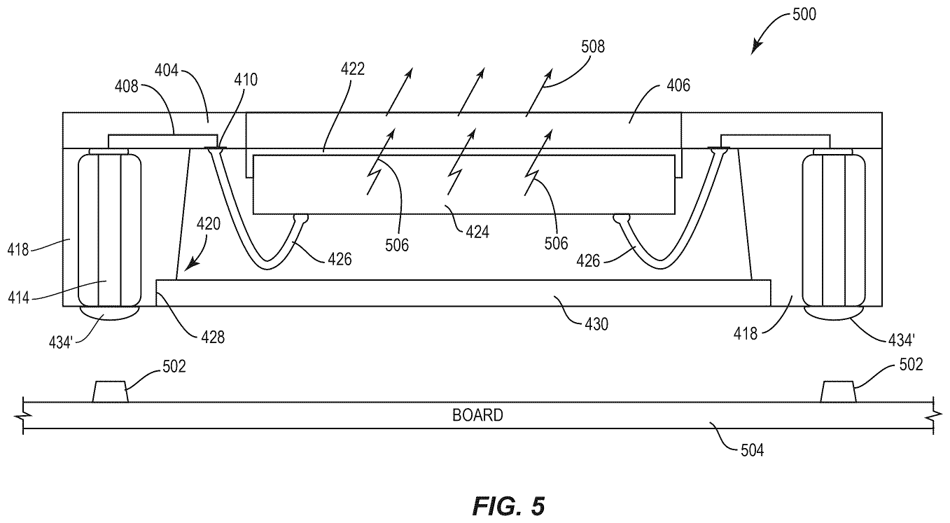

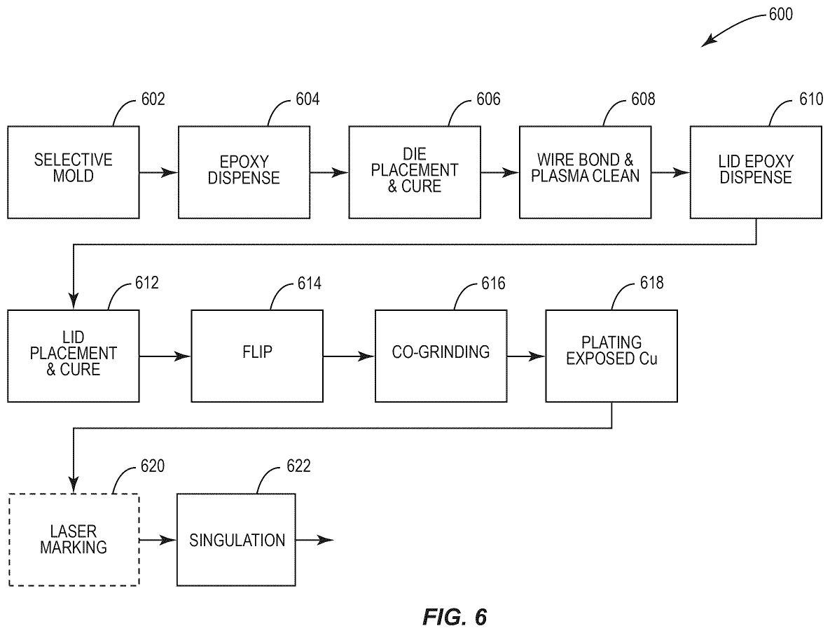

This process 300 results in the package 500 illustrated in FIG. 5. In use, the package 500 is flipped, and the contacts 434′ are configured to be attached to complementary contacts 502 on a board 504. Heat 506 flows from the internal circuitry through a “bottom” of the die 424 to the heat spreader element 406 and out the “top” of the package 500, where it can radiate (generally at 508) or be coupled to another heat transfer device (e.g., a constant temperature plane, a fan, or the like).

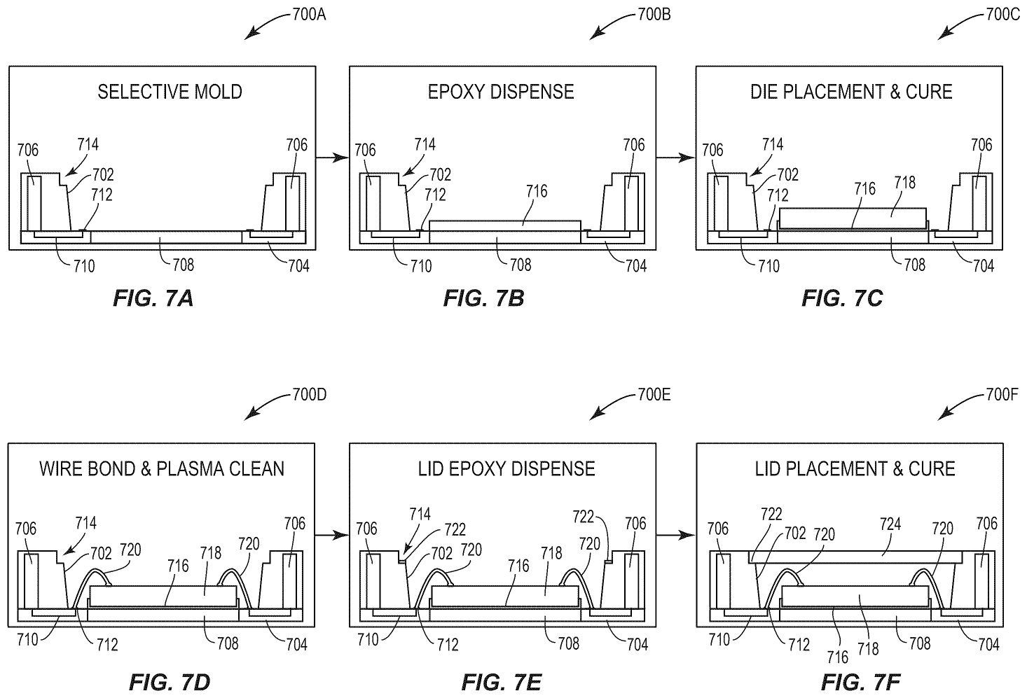

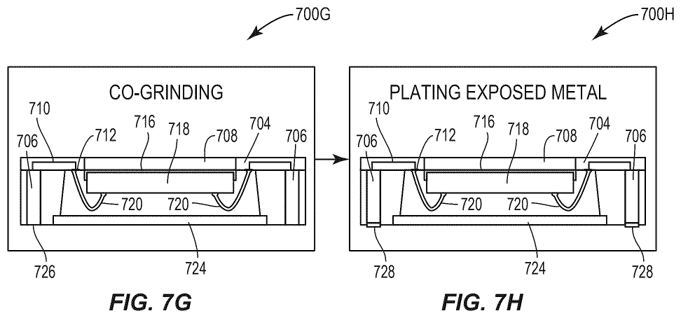

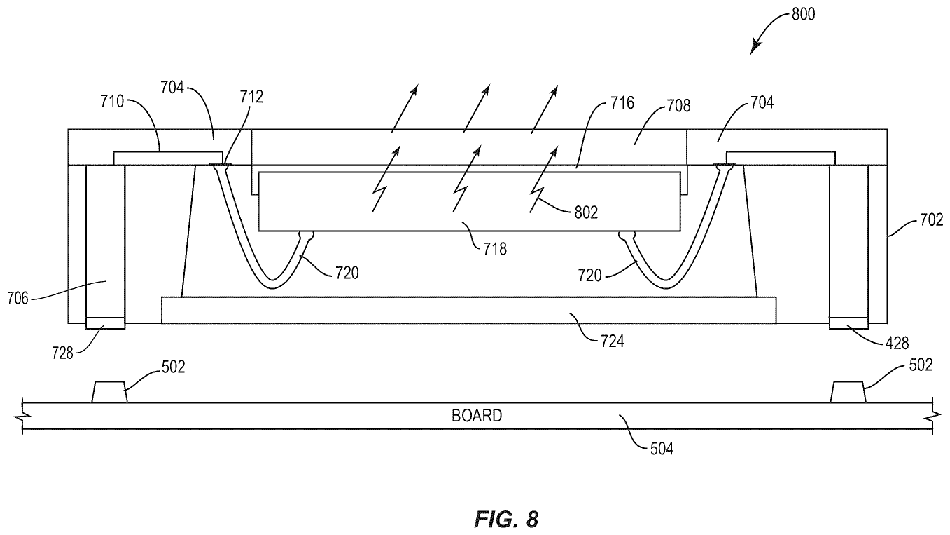

A second aspect is similar, but instead of a via bar with vias that work with solder balls, the second aspect uses metal plating on metal posts, as better explained by process 600, FIGS. 7A-7H, and FIG. 8.

A process 600 begins by creating a selective mold 702 (block 602, FIG. 7A) on a metalized laminate structure 704 to hold metal columns or posts 706 in a desired location to form intermediate structure 700A. The posts 706 may be a conductive metal such as copper, silver, gold, or the like. The metalized laminate structure 704 is similar to laminate structure 404 and also includes a heat spreader element 708, internal conductors 710 which electrically couple the posts 706 to pads 712 on the metalized laminate structure 704. The mold 702 includes an edge (also referred to as a shoulder or lip) 714 configured to receive a lid, as explained below.

The process 600 continues by dispensing an epoxy 716 (block 604, FIG. 7B) on the metalized laminate structure 704 and particularly over the heat spreader element 708 to form intermediate structure 700B. Then a die 718 is placed on the epoxy 716 and cured (block 606, FIG. 7C) to form intermediate structure 700C. The die 718 is coupled to the pads 712 by wire bonds 720 and plasma cleaned (block 608, FIG. 7D) to form intermediate structure 700D. This forms an electrical connection between internal circuitry of the die 718 to the columns 706 through the wire bonds 720, pads 712, and internal conductors 710.

The process 600 continues by dispensing a lid epoxy 722 (block 610, FIG. 7E) on the lip 714 to form intermediate structure 700E. The lid 724 is then placed on the lip 714 and the lid epoxy 722 is cured (block 612, FIG. 7F) to form intermediate structure 700F. The intermediate structure 700F is then flipped (block 614), and co-grinding occurs (block 616, FIG. 7G) to form intermediate structure 700G. The co-grinding exposes a surface 726 of the posts 706. The exposed surface 726 is then metal plated (block 618, FIG. 7H) to form contacts 728 to form intermediate product 700H where contacts 728 are configured to attach to contacts 502 on a board 504 (see FIG. 8). Optionally, laser marking may be done (block 620) and singulation (block 622).

The result of the process 600 is a package 800, as illustrated in FIG. 8. Heat 802 generated by internal circuitry within the die 718 flows up to the heat spreader element 708 and then may be radiated away or collected by some other heat dissipation element.

The top cooled air cavities, according to aspects disclosed herein, may be provided in or integrated into any processor-based device that has high-power circuits that may need cooling, including, for example, aerospace, defense and/or cellular base stations. While not currently en vogue, use of air cavities may, in the future, expand to consumer electronics, and aspects of the present disclosure may be applicable to such devices as well.

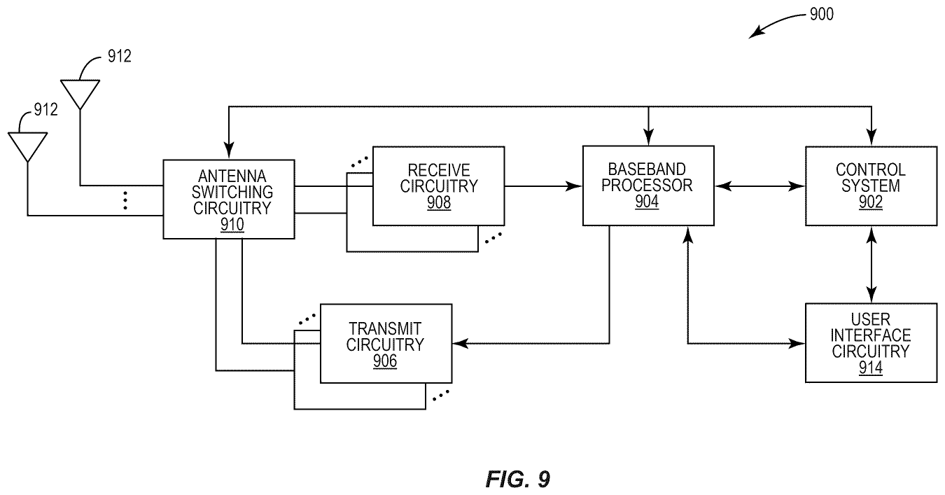

FIG. 9 is a schematic diagram of an exemplary communication device 900 that may have a high-power circuit in which the top cooled air cavity of the present disclosure can be provided. Herein, the communication device 900 can be any type of communication device, such as those listed above, as well as access points, base stations (e.g., eNB or gNB), and any other type of wireless communication devices that support wireless communications, such as cellular, wireless local area network (WLAN), Bluetooth, Ultra-wideband (UWB), and near field communications. Additionally, the device need not specifically be a communication device, but could just include a wireless transmitter (e.g., radar or the like), but in the interests of providing at least one use case, a communication device 900 is discussed.

More particularly, the communication device 900 will generally include a control system 902, a baseband processor 904, transmit circuitry 906, receive circuitry 908, antenna switching circuitry 910, multiple antennas 912, and user interface circuitry 914. In a non-limiting example, the control system 902 can be a field-programmable gate array (FPGA) or an application-specific integrated circuit (ASIC), as an example. In this regard, the control system 902 can include at least a microprocessor(s), an embedded memory circuit(s), and a communication bus interface(s). The receive circuitry 908 receives radio frequency signals via the antennas 912 and through the antenna switching circuitry 910 from one or more base stations. A low noise amplifier and a filter of the receive circuitry 908 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 904 processes the digitized received signal to extract the information or data bits conveyed in the received signal. This processing typically comprises demodulation, decoding, and error correction operations. The baseband processor 904 is generally implemented in one or more digital signal processors (DSPs) and ASICs.

For transmission, the baseband processor 904 receives digitized data, which may represent voice, data, or control information, from the control system 902, which it encodes for transmission. The encoded data is output to the transmit circuitry 906, where a digital-to-analog converter(s) (DAC) converts the digitally encoded data into an analog signal, and a modulator modulates the analog signal onto a carrier signal that is at a desired transmit frequency or frequencies. A power amplifier (which may be a high-power component amenable to inclusion in an air cavity) will amplify the modulated carrier signal to a level appropriate for transmission and deliver the modulated carrier signal to the antennas 912 through the antenna switching circuitry 910. The multiple antennas 912 and the replicated transmit and receive circuitries 906, 908 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A package comprising:
a metalized laminate comprising a heat spreader element;
a sidewall positioned on a first side of the metalized laminate, the sidewall comprising an external contact configured to couple electrically to an external substrate;
a die positioned on the first side of the metalized laminate proximate the heat spreader element; and
a lid connected to the sidewall, proximate the external contact, and spaced from the metalized laminate, wherein the lid, the metalized laminate, and the sidewall delimit an air cavity with the die positioned inside the air cavity.

2. The package of claim 1, wherein the die is attached to the metalized laminate with an epoxy.

3. The package of claim 1, wherein the lid is connected to the sidewall with an epoxy.

4. The package of claim 1, wherein the metalized laminate comprises a contact pad and an internal conductor, wherein the die is electrically coupled to the contact pad through a wire bond.

5. The package of claim 4, wherein the sidewall comprises a sidewall conductor electrically coupled to the external contact and the internal conductor.

6. The package of claim 5, wherein the sidewall conductor comprises a via and the sidewall comprises a via bar.

7. The package of claim 5, wherein the sidewall conductor comprises a conductive column.

8. The package of claim 1, wherein the external contact comprises a solder ball.

9. The package of claim 1, wherein the external contact comprises a metal plate.

10. A communication device comprising:
a transceiver comprising a high-power power amplifier, the high-power power amplifier positioned in a die in an air cavity, the air cavity delimited by a package, the package comprising:
a metalized laminate comprising a heat spreader element;
a sidewall positioned on a first side of the metalized laminate, the sidewall comprising an external contact configured to couple electrically to an external substrate;
the die positioned on the first side of the metalized laminate proximate the heat spreader element; and
a lid connected to the sidewall, proximate the external contact, and spaced from the metalized laminate, wherein the lid, the metalized laminate, and the sidewall delimit the air cavity with the die positioned inside the air cavity.

11. A method of forming a top-side cooled air cavity, comprising:
forming a metalized laminate structure comprising a heat spreader element;
positioning a sidewall on a first side of the metalized laminate structure;
positioning a die on the first side of the metalized laminate structure;
positioning a lid over the die on the sidewall, thereby delimiting an air cavity with the die inside the air cavity; and
exposing an external contact on a surface of the sidewall distal from the first side of the metalized laminate structure.

12. The method of claim 11, further comprising placing an epoxy on the first side of the metalized laminate structure to attach the die to the metalized laminate structure.

13. The method of claim 11, further comprising placing an epoxy on a lip of the sidewall to attach the lid to the sidewall.

14. The method of claim 11 wherein positioning the sidewall comprises placing a via bar on the first side of the metalized laminate structure and forming a mold material over the via bar.

15. The method of claim 11, wherein positioning the sidewall comprises forming a mold material over a conductive post.

16. The method of claim 11, further comprising wire bonding the die to a contact on the first side of the metalized laminate structure.

17. The method of claim 16, further comprising providing an electrical path from the contact to the external contact.

18. The method of claim 17, wherein providing the electrical path comprises using a internal conductor within the heat spreader element to couple to a conductor in the sidewall.

19. The method of claim 11, further comprising grinding the sidewall to expose a conductor in the sidewall.

20. The method of claim 19, further comprising adding a solder ball to the exposed conductor.
